(19) United States
(12) Patent Application Publication
(10) Pub. No.: US 2018/0374552 A1
(43) Pub. Date: Dec. 27, 2018

(54) MEMORY SYSTEM AND OPERATION METHOD THEREOF

(71) Applicant: SK hynix Inc., Gyeonggi-do (KR)

(72) Inventor: Jiman HONG, Gyeonggi-do (KR)

(21) Appl. No.: 15/881,243

(22) Filed: Jan. 26, 2018

(30) Foreign Application Priority Data
Jun. 23, 2017 (KR) 10-2017-0079710

(51) Int. Cl. G11C 16/34; G11C 16/26; G06F 11/10; G11C 29/52; G11C 16/04

(52) U.S. Cl. CPC G11C 16/3459; G11C 16/26; G11C 16/0408; G11C 29/52; G06F 11/1068

(57) ABSTRACT

A memory system comprising: a nonvolatile memory device including a plurality of pages, and suitable for performing one among a first program operation of performing program and verify operations according to an incremental step pulse programming (ISPP) scheme and a second program operation of first performing a verify operation and then performing program and verify operations according to the ISPP scheme when the program operation is to be performed to each of the plurality of pages; and a controller suitable for controlling the nonvolatile memory device to perform the second program operation when a target page meets an operation condition of a reprogram, and to perform the first program operation when the target page does not meet the operation condition of the reprogram.

### CROSS-REFERENCE TO RELATED APPLICATIONS

The present application claims priority to Korean Patent Application No. 10-2017-0079710, filed on Jun. 23, 2017, which is incorporated herein by reference in its entirety.

### BACKGROUND

### 1. Field

Exemplary embodiments of the present invention relate to a memory system. Particularly, the exemplary embodiments relate to a memory system including a non-volatile memory device, and a method for operating the memory system.

### 2. Description of the Related Art

The paradigm for computing environments is shifting toward ubiquitous computing, which allows users to use computer systems anytime anywhere. For this reason, the demands for portable electronic devices such as mobile phones, digital cameras, and laptop computers are increasing. Those electronic devices generally include a memory system using a memory device as a data storage device. The data storage device may be used as a main memory unit or an auxiliary memory unit of a portable electronic device.

Since the data storage device using a memory device has no mechanical driving unit, it may have excellent stability and durability. Also, the data storage device has a quick data access rate with low power consumption. Non-limiting examples of the data storage device having such advantages include Universal Serial Bus (USB) memory devices, memory cards of diverse interfaces, Solid-State Drives (SSD), and the like.

### SUMMARY

Various embodiments of the present invention may provide a nonvolatile memory device capable of performing a reprogram operation, which prevents an over-program, a memory system including the memory device and an operating method of the memory system.

In accordance with an embodiment of the present invention, a memory system may include a nonvolatile memory device, to which selected one between a first program process and a second program process can be performed. In the first program process, a program operation and a verify operation may be performed according to the incremental step pulse programming (ISPP) scheme. In the second program process, a verify operation may be first performed and then a program operation and a verify operation may be performed according to the incremental step pulse programming (ISPP) scheme. The memory system may take the second program process to the nonvolatile memory device when an operation condition is met, and may take the first program process to the nonvolatile memory device in the other situation. The operation condition may indicate that the memory system performs a reprogram operation to the nonvolatile memory device.

Therefore, the memory system may prevent an over-program, which may occur due to an initial program pulse of the ISPP scheme in the operation condition for a reprogram operation.

In accordance with an embodiment of the present invention, a memory system comprising: a nonvolatile memory device including a plurality of pages, and suitable for performing one among a first program operation of performing program and verify operations according to an incremental step pulse programming (ISPP) scheme and a second program operation of first performing a verify operation and then performing program and verify operations according to the ISPP scheme when the program operation is to be performed to each of the plurality of pages; and a controller suitable for controlling the nonvolatile memory device to perform the second program operation when a target page meets an operation condition of a reprogram, and to perform the first program operation when the target page does not meet the operation condition of the reprogram.

Preferably, the controller includes an ECC unit suitable for recovering, when a read data read from each of the plurality of pages include failed bits under a first threshold, the read data by correcting the failed bits.

Preferably, the controller determines, when a program operation is interrupted due to a sudden power off (SPO) while programming an input data into one among the plurality of pages and a power is back on again, whether or not failed bits of a read data read from the program-interrupted page are correctable through the ECC unit, and wherein the controller programs, when the failed bits of the read data read from the program-interrupted page are determined to be correctable through the ECC unit, a recovered data into the program-interrupted page through the second program operation and provides the host with information indicating completion of the second program operation to the program-interrupted page.

Preferably, when the failed bits of the read data read from the program-interrupted page are determined to be uncorrectable through the ECC unit, the controller invalidates the program-interrupted page, provides the host with information indicating program failure of the program-interrupted page, receives the input data again from the host, and programs the re-provided input data into another page other than the program-interrupted page through the first program operation.

Preferably, the controller performs a read determination operation of determining whether or not failed bits of read data read from the program-interrupted page are over a predetermined second threshold smaller than the first threshold even when the failed bits of the read data are under the first threshold, and wherein the controller performs, when failed bits of read data read from the program-interrupted page are determined to be over a second threshold even when the failed bits of the read data are under the first threshold as a result of the read determination operation, a make-up program operation of programming a recovered data, which is recovered by the ECC unit, into the program-interrupted page through the second program operation.

Preferably, the controller simultaneously performs the read determination operation when a read data read from the program-interrupted page as a result of a read operation performed in response to a request from the host includes failed bits, and wherein the controller performs, after the read determination operation, the make-up program operation when the nonvolatile memory device is in an idle state.

Preferably, the second threshold is 70% of the first threshold.

In accordance with an embodiment of the present invention, an operating method of a memory system including a nonvolatile memory device including a plurality of pages, and suitable for performing one among a first program operation of performing program and verify operations according to an incremental step pulse programming (ISPP) scheme and a second program operation of first performing a verify operation and then performing program and verify operations according to the ISPP scheme when the program operation is to be performed to each of the plurality of pages, the operating method comprising: a determining step of determining whether or not each of the plurality of pages meets an operation condition of a reprogram; and a program controlling step of controlling the nonvolatile memory device to perform the second program operation when a target page meets an operation condition of a reprogram, and to perform the first program operation when the target page does not meet the operation condition of the reprogram.

Preferably, further comprising a recovering step of recovering, when a read data read from each of the plurality of pages includes failed bits under a first threshold, the read data by correcting the failed bits.

Preferably, the determining step includes a recovery determining step of determining, when a program operation is interrupted due to a sudden power off (SPO) while programming an input data provided from a host into a program-interrupted page and a power is back on again, whether or not failed bits of a read data read from the program-interrupted page are correctable through the recovering step.

Preferably, wherein when the failed bits of the read data read from the program-interrupted page are determined to be correctable through the ECC unit by the recovery determining step, the program controlling step includes: programing a recovered data, which is recovered through the recovering step, into the program-interrupted page through the second program operation; and providing the host with information indicating completion of the second program operation to the program-interrupted page.

Preferably, wherein when the failed bits of the read data read from the program-interrupted page are determined to be uncorrectable through the ECC unit by the recovery determining step, the program controlling step includes: invalidating the program-interrupted page; providing the host with information indicating program failure of the program-interrupted page; and receiving, after the second provision step, the input data again from the host, and programming the re-provided input data into another page other than the program-interrupted page through the first program operation.

Preferably, wherein the determining step includes a read determination step of determining whether or not failed bits of read data read from the program-interrupted page are over a predetermined second threshold smaller than the first threshold even when the failed bits of the read data are under the first threshold.

Preferably, wherein when failed bits of read data read from the program-interrupted page are determined to be over a second threshold even when the failed bits of the read data are under the first threshold as a result of the read determination step, the program controlling step includes a make-up program step of programming a recovered data, which is recovered by the recovering step, into the program-interrupted page through the second program operation.

Preferably, further comprising: simultaneously performing the read determination step when a read data read from the program-interrupted page as a result of a read operation performed in response to a request from the host includes failed bits; and performing, after the read determination step, the make-up program step when the nonvolatile memory device is in an idle state.

Preferably, wherein the second threshold is 70% of the first threshold.

In accordance with an embodiment of the present invention, a memory system comprising: a memory device including a plurality of pages; and a controller suitable for controlling the memory device to perform a verification operation and then a program operation to a program-interrupted one among the plurality of pages, wherein the controller detects one or more under a target voltage level among memory cells included in the program-interrupted page through the verification operation, and wherein the program operation may include one or more cycles of program and verification to the memory cells under the target voltage level.

### BRIEF DESCRIPTION OF THE DRAWINGS

FIG. 1 is a block diagram illustrating a data processing system including a memory system in accordance with an embodiment of the present invention.

FIG. 2 is a schematic diagram illustrating an exemplary configuration of a memory device employed in the memory system of FIG. 1.

FIG. 3 is a circuit diagram illustrating an exemplary configuration of a memory cell array of a memory block in the memory device of FIG. 2.

FIG. 4 is a schematic diagram illustrating an exemplary three-dimensional structure of the memory device of FIG. 2.

FIGS. 5 to 6 are diagrams illustrating an example of a reprogram operation performed in a memory system according to an embodiment of the present invention.

FIGS. 7A to 7B are diagrams describing a program operation of the nonvolatile memory device shown in FIGS. 5 to 6.

FIGS. 8 to 16 are diagrams schematically illustrating application examples of the data processing system of FIG. 1, in accordance with various embodiment of the present invention.

### DETAILED DESCRIPTION

Various embodiments of the present invention are described below in more detail with reference to the accompanying drawings. We note, however, that the present invention may be embodied in different other embodiments, forms and variations thereof and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments. When an element is referred to as being connected or coupled to another element, it should be understood that the former can be directly connected or coupled to the latter, or electrically connected or coupled to the latter via an intervening element therebetween.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention.

As used herein, singular forms are intended to include the plural forms as well, unless the context clearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

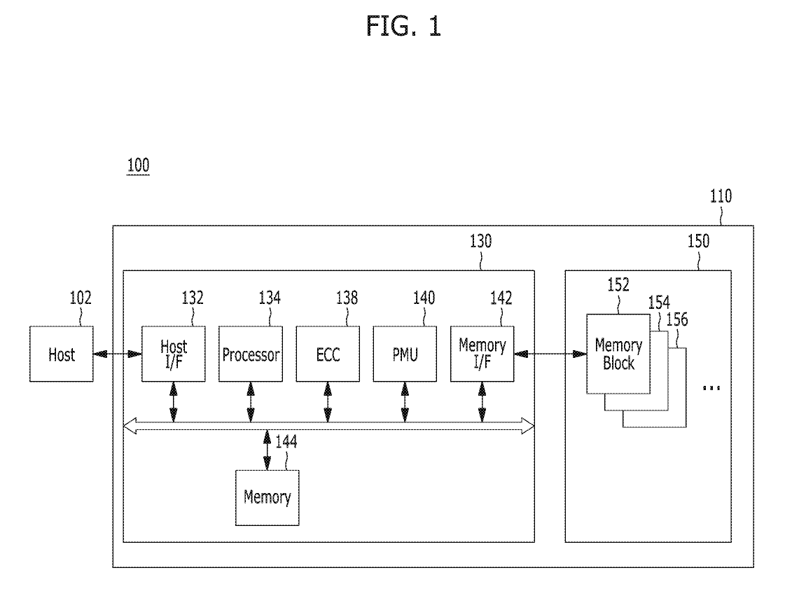

FIG. 1 is a block diagram illustrating a data processing system 100 in accordance with an embodiment of the present invention.

Referring to FIG. 1, the data processing system 100 may include a host 102 operatively coupled to a memory system 110.

The host 102 may include, for example, a portable electronic device such as a mobile phone, an MP3 player and a laptop computer or an electronic device such as a desktop computer, a game player, a TV, a projector and the like.

The memory system 110 may operate in response to a request from the host 102, and in particular, store data to be accessed by the host 102. The memory system 110 may be used as a main memory system or an auxiliary memory system of the host 102. The memory system 110 may be implemented with any one of various types of storage devices, which may be electrically coupled with the host 102, according to a protocol of a host interface. Examples of suitable storage devices include a solid state drive (SSD), a multimedia card (MMC), an embedded MMC (eMMC), a reduced size MMC (RS-MMC) and a micro-MMC, a secure digital (SD) card, a mini-SD and a micro-SD, a universal serial bus (USB) storage device, a universal flash storage (UFS) device, a compact flash (CF) card, a smart media (SM) card, a memory stick, and the like.

The storage devices for the memory system 110 may be implemented with a volatile memory device such as a dynamic random access memory (DRAM) and a static RAM (SRAM), and nonvolatile memory device such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), resistive RAM (RRAM) and a flash memory.

The memory system 110 may include a memory device 150, which stores data to be accessed by the host 102, and a controller 130 which may control storage of data in the memory device 150.

The controller 130 and the memory device 150 may be integrated into a single semiconductor device, which may be included in the various types of memory systems as exemplified above.

The memory system 110 may be configured as part of, for example, a computer, an ultra-mobile PC (UMPC), a workstation, a netbook, a personal digital assistant (PDA), a portable computer, a web tablet, a tablet computer, a wireless phone, a mobile phone, a smart phone, an e-book, a portable multimedia player (PMP), a portable game player, a navigation system, a black box, a digital camera, a digital multimedia broadcasting (DMB) player, a 3D television, a smart television, a digital audio recorder, a digital audio player, a digital picture recorder, a digital picture player, a digital video recorder, a digital video player, a storage configuring a data center, a device capable of transmitting and receiving information under a wireless environment, one of various electronic devices configuring a home network, one of various electronic devices configuring a computer network, one of various electronic devices configuring a telematics network, a radio frequency identification (RFID) device, or one of various component elements configuring a computing system.

The memory device 150 may be a nonvolatile memory device and may retain data stored therein even though power is not supplied. The memory device 150 may store data provided from the host 102 through a write operation, and provide data stored therein to the host 102 through a read operation. The memory device 150 may include a plurality of memory blocks 152 to 156, where each of the memory blocks 152 to 156 may include a plurality of pages. Each of the pages may include a plurality of memory cells to which a plurality of word lines (WL) are electrically coupled.

The controller 130 may control overall operations of the memory device 150, such as read, write, program, and erase operations. For example, the controller 130 of the memory system 110 may control the memory device 150 in response to a request from the host 102. The controller 130 may provide the data read from the memory device 150, to the host 102, and/or may store the data provided from the host 102 into the memory device 150.

The controller 130 may include a host interface (I/F) unit 132, a processor 134, an error correction code (ECC) unit 138, a power management unit (PMU) 140, a memory device controller 142 such as a NAND flash controller (NFC), and a memory 144, all operatively coupled via an internal bus.

The host interface unit 132 may process commands and data provided from the host 102, and may communicate with the host 102 through at least one of various interface protocols such as universal serial bus (USB), multimedia card (MMC), peripheral component interconnect-express (PCI-E), small computer system interface (SCSI), serial-attached SCSI (SAS), serial advanced technology attachment (SATA), parallel advanced technology attachment (PATA), small computer system interface (SCSI), enhanced small disk interface (ESDI), and integrated drive electronics (IDE).

The ECC unit 138 may detect and correct errors in the data read from the memory device 150 during the read operation. The ECC unit 138 may not correct error bits when the number of the error bits is greater than or equal to a threshold number of correctable error bits, and may output an error correction fail signal indicating failure in correcting the error bits.

The ECC unit 138 may perform an error correction operation based on a coded modulation such as a low density parity check (LDDC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), and so on. The ECC unit 138 may include all circuits, modules, systems, or devices for the error correction operation.

The PMU 140 may provide and manage power of the controller 130.

The memory device controller 142 may serve as a memory/storage interface between the controller 130 and the memory device 150 to allow the controller 130 to control the memory device 150 in response to a request from the host 102. The memory device controller 142 may generate a control signal for the memory device 150 and process data to be provided to the memory device 150 under the control of the processor 134. The memory device controller 142 may work as an interface (e.g., a NAND flash interface) for processing a command and data between the controller 130 and the memory device 150. Specifically, the memory device controller 142 may support data transfer between the controller 130 and the memory device 150. A suitable memory/storage interface may be selected depending upon the type of the memory device 150.

The memory 144 may serve as a working memory of the memory system 110 and the controller 130, and store data for driving the memory system 110 and the controller 130. The controller 130 may control the memory device 150 in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be implemented with a volatile memory. The memory 144 may be implemented with a static random access memory (SRAM) or a dynamic random access memory (DRAM). Although FIG. 1 illustrates the memory 144 disposed within the controller 130, the present disclosure is not limited thereto. That is, the memory 144 may be disposed within or out of the controller 130. In an embodiment, the memory 144 may be embodied by an external volatile memory having a memory interface transferring data between the memory 144 and the controller 130.

The processor 134 may control the overall operations of the memory system 110. The processor 134 may drive firmware, which is referred to as a flash translation layer (FTL), to control the general operations of the memory system 110.

A FTL may perform an operation as an interface between the host 102 and the memory device 150. The host 102 may request to the memory device 150 write and read operations through the FTL.

The FTL may manage operations of address mapping, garbage collection, wear-leveling, and so forth. Particularly, the FTL may store map data. Therefore, the controller 130 may map a logical address, which is provided from the host 102, to a physical address of the memory device 150 through the map data. The memory device 150 may perform an operation like a general device because of the address mapping operation. Also, through the address mapping operation based on the map data, when the controller 130 updates data of a particular page, the controller 130 may program new data into another empty page and may invalidate old data of the particular page due to a characteristic of a flash memory device. Further, the controller 130 may store map data of the new data into the FTL.

The processor 134 may be implemented with a microprocessor or a central processing unit (CPU).

A management unit (not shown) may be included in the processor 134, and may perform bad block management of the memory device 150. The management unit may find bad memory blocks included in the memory device 150, which are in unsatisfactory condition for further use, and perform bad block management on the bad memory blocks. When the memory device 150 is a flash memory, for example, a NAND flash memory, a program failure may occur during the write operation, for example, during the program operation, due to characteristics of a NAND logic function. During the bad block management, the data of the program-failed memory block or the bad memory block may be programmed into a new memory block. Also, the bad blocks due to a program failure seriously deteriorates the efficiency of the memory device 150 having a 3D stack structure and the reliability of the memory system 100, and thus reliable bad block management is required.

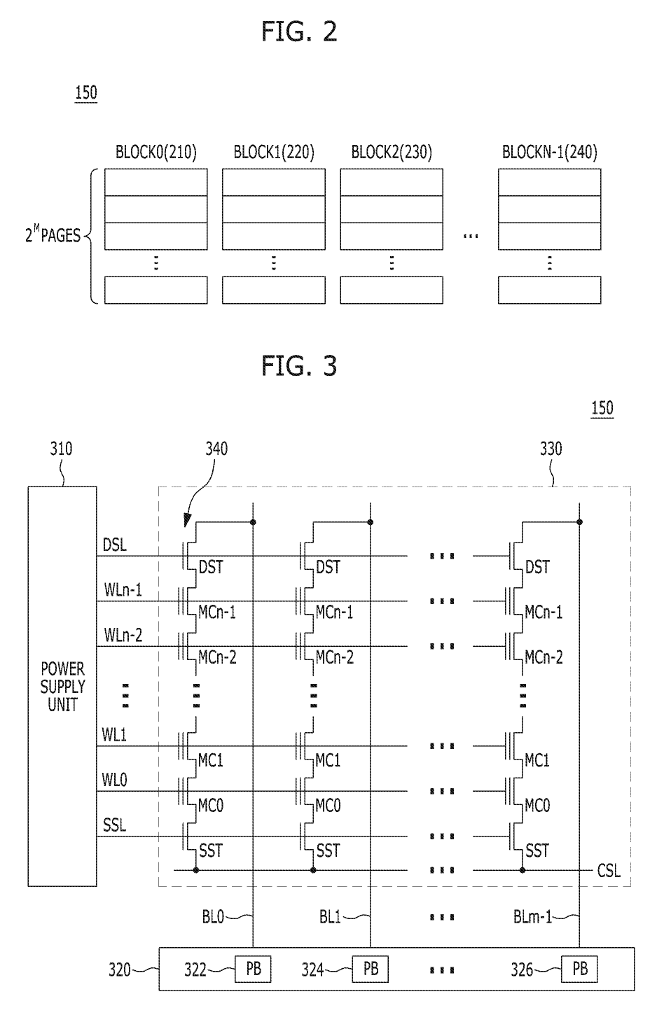

FIG. 2 is a schematic diagram illustrating the memory device 150.

Referring to FIG. 2, the memory device 150 may include the plurality of memory blocks BLOCK 0 to BLOCKN-1, and each of the blocks BLOCK 0 to BLOCKN-1 may include a plurality of pages, for example, 2^{M} pages, the number of which may vary according to circuit design. The memory device 150 may include a plurality of memory blocks, as single level cell (SLC) memory blocks and multi-level cell (MLC) memory blocks, according to the number of bits which may be stored or expressed in each memory cell. The SLC memory block may include a plurality of pages which are implemented with memory cells each capable of storing 1-bit data. The MLC memory block may include a plurality of pages which are implemented with memory cells each capable of storing multi-bit data, for example, two or more-bit data. An MLC memory block including a plurality of pages which are implemented with memory cells that are each capable of storing 3-bit data may be defined as a triple level cell (TLC) memory block.

FIG. 3 is a circuit diagram illustrating a memory block 330 in the memory device 150.

Referring to FIG. 3, the memory block 330 which corresponds to any of the plurality of memory blocks 152 to 156 of the memory device 150.

Referring to FIG. 3, the memory block 152 of the memory device 150 may include a plurality of cell strings 340, which are electrically coupled to bit lines BL0 to BLm-1, respectively. The cell string 340 of each column may include at least one drain select transistor DST and at least one source select transistor SST. A plurality of memory cells or a plurality of memory cell transistors MC0 to MCn-1 may be electrically coupled in series between the select transistors DST and SST. The respective memory cells MC0 to MCn-1 may be configured by single level cells (SLC) each of which may store 1 bit of information, or by multi-level cells (MLC) each of which may store data information of a plurality of bits. The cell strings 340 may be electrically coupled to the corresponding bit lines BL0 to BLm-1, respectively. For reference, in FIG. 3, ‘DSL’ denotes a drain select line, ‘SSL’ denotes a source select line, and ‘CSL’ denotes a common source line.

While FIG. 3 only shows, as an example, the memory block 152 which is configured by NAND flash memory cells, it is to be noted that the memory block 152 of the memory device 150 according to the embodiment is not limited to NAND flash memory and may be configured by NOR flash memory, hybrid flash memory in which at least two kinds of memory cells are combined, or one-NAND flash memory in which a controller is built in a memory chip. The operational characteristics of a semiconductor device may be applied to not only a flash memory device in which a charge storing layer is configured by conductive floating gates, but also a charge trap flash (CTF) in which a charge storing layer is configured by a dielectric layer.

A power supply unit 310 of the memory device 150 may provide word line voltages, for example, a program voltage, a read voltage and a pass voltage, to be supplied to respective word lines according to an operation mode and voltages to be supplied to bulks, for example, well regions in which the memory cells are formed. The power supply unit 310 may perform a voltage generating operation under the control of a control circuit (not shown). The power supply unit 310 may generate a plurality of variable read voltages to generate a plurality of read data, select one of the memory blocks or sectors of a memory cell array under the control of the control circuit, select one of the word lines of the selected memory block, and provide the word line voltages to the selected word line and unselected word lines.

A read/write circuit 320 of the memory device 150 may be controlled by the control circuit, and may serve as a sense amplifier or a write driver according to an operation mode. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

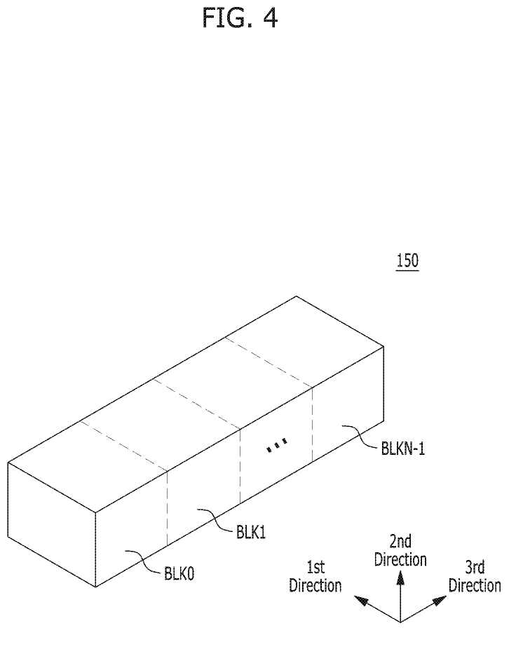

FIG. 4 is a schematic diagram illustrating a three-dimensional (3D) structure of the memory device 150 shown in FIGS. 1 to 3.

The memory device 150 may be embodied by a 2D or 3D memory device. Specifically, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN-1 each having a 3D structure (or vertical structure).

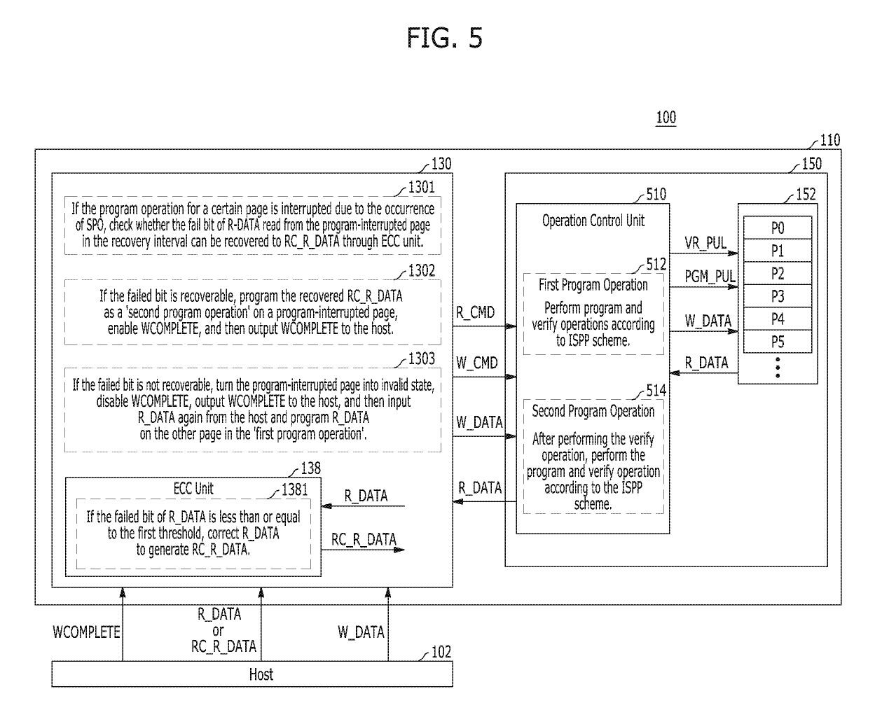

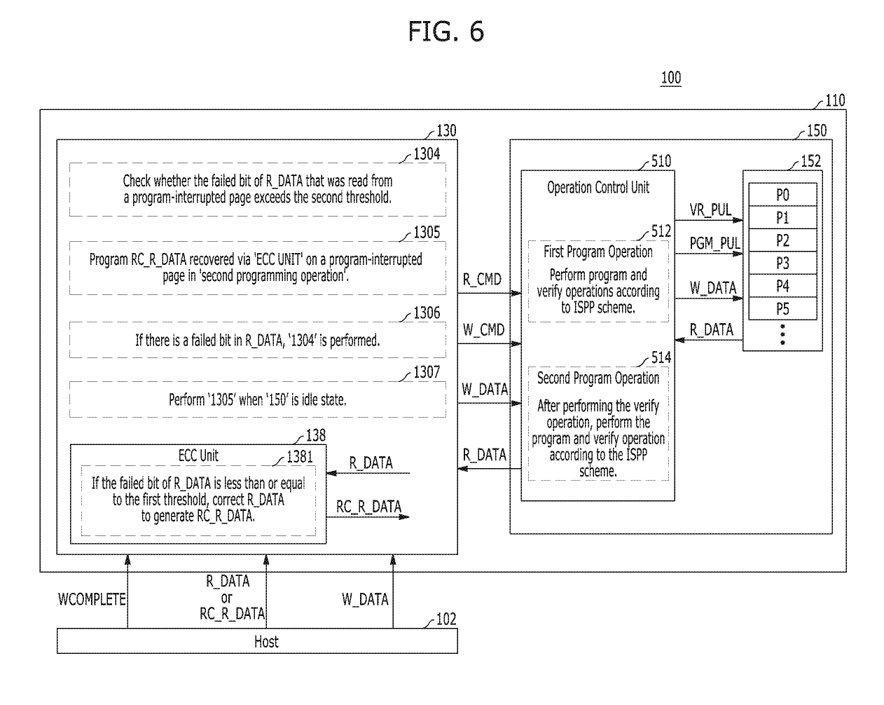

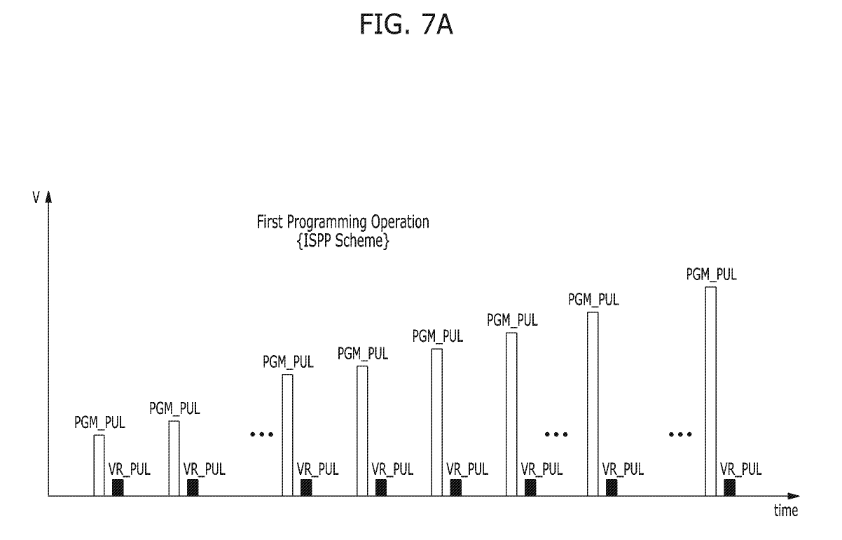

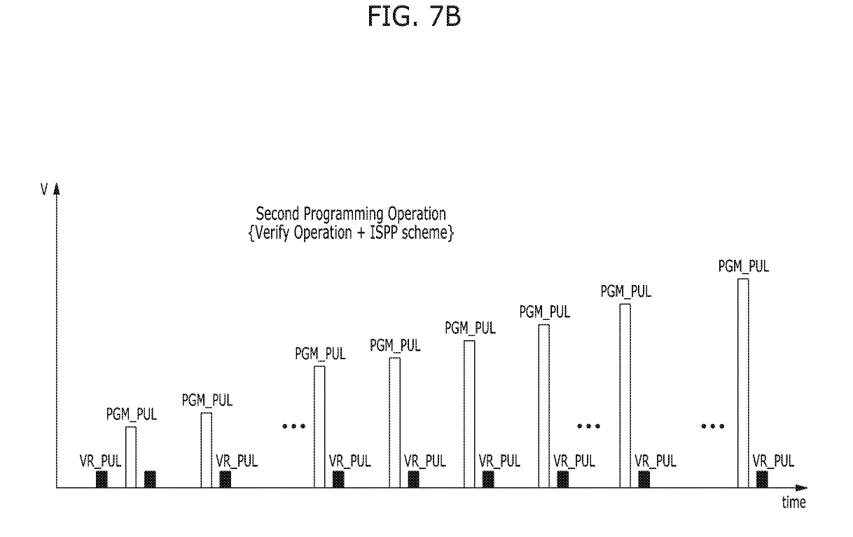

FIGS. 5 and 6 are diagrams illustrating examples of a reprogram operation of a memory system in accordance with an embodiment of the present invention. For example, in FIGS. 5 and 6, the memory system 110 including the nonvolatile memory device 150 with reference to the memory system 110 of FIG. 1 is shown. FIGS. 7A to 7B are diagrams describing a program operation of the nonvolatile memory device shown in FIGS. 5 to 6. In describing various program operations in accordance with the present disclosure, references will be made to FIGS. 5 to 7B.

As described with reference to FIG. 1, the nonvolatile memory device 150 may include a plurality of memory blocks 152 to 156. Also, as described with reference to FIG. 2, each of the plurality of memory blocks 152 to 156 may include a plurality of pages.

The nonvolatile memory device 150 may further include an operation control unit 510. At this time, the operation control unit 510 may control operations of the nonvolatile memory device 150, and may include the voltage supply unit 310 and the read/write circuit 320 described with reference to FIG. 3.

The operation control unit 510 may selectively perform one among first and second program operations 512 and 514 under the control of the controller 130.

Particularly, the nonvolatile memory device 150 in accordance with an embodiment of the present invention shown in FIGS. 5 and 6 may perform a program operation to each of the plurality of pages P0, P1, P2, P3, P4, P5, . . . (hereinafter, referred to as ‘plurality of pages P0 to P5’) in response to input data W_DATA and a program command W_CMD provided from the controller 130.

Also, the nonvolatile memory device 150 may select one among a first program operation 512 and a second program operation 514, and may perform the selected program operation, under the control of the controller 130.

At this time, the nonvolatile memory device 150 may perform a first program operation 512 according to a well-known program operation, that is, the incremental step pulse program (ISPP) scheme.

Particularly, a general nonvolatile memory device such as the flash memory device performs a program operation according to the incremental step pulse program (ISPP) scheme. According to the ISPP scheme, an input data W_DATA is programmed into each of memory cells coupled to a word line corresponding to a page, to which a program operation is performed, by applying a program pulse PGM_PUL, a voltage level of which increases stepwisely. Also, according to the ISPP scheme, whenever the program pulse PGM_PUL is applied to the word line, a verify pulse VR_PUL is used in order to verify that each threshold voltage level of the memory cells coupled to the word line reaches a target voltage level, or that the input data W_DATA is normally programmed into the word line. That is, according to the ISPP scheme, the program pulse PGM_PUL is first used and then the verify pulse VR_PUL is used in order to verify that each threshold voltage level of the memory cells coupled to the word line reaches a target voltage level because of the firstly used program pulse PGM_PUL. That is, when some of the memory cells have the threshold voltages of the target voltage level as the verification result with the verify pulse VR_PUL, the program pulse PGM_PUL is controlled not to be applied to the memory cells having the threshold voltages of the target voltage level and is controlled to have greater voltage level than previous voltage level at next application of the program pulse PGM_PUL to the word line.

For example, as shown in FIG. 7A, the program pulse PGM_PUL and the verify pulse VR_PUL are alternately applied to a word line corresponding to a page according to the ISPP scheme. Such ISPP scheme is well-known art and a general flash memory device performs a program operation according to the ISPP scheme.

To summarize, the nonvolatile memory device 150 in accordance with an embodiment of the present invention as shown in FIGS. 5 and 6 may select a program operation of the first program operation 512 and may perform the selected program operation, which means that the nonvolatile memory device 150 may perform the program operation and the verify operation according to the ISPP scheme.

During the second program operation 514, the nonvolatile memory device 150 first may perform a verify operation and then perform a well-known program operation (that is, the ISPP scheme) according to the result of the verification operation.

During the second program operation 514, the nonvolatile memory device 150 may first apply the verify pulse VR_PUL to a word line corresponding to a page, to which the program operation is performed, in order to check whether some among memory cells coupled to the word line have threshold voltages of a target voltage level, and then performs the well-known program operation according to the ISPP scheme to memory cells other than the memory cells having the threshold voltages of the target voltage level.

Therefore, through the second program operation 514, the nonvolatile memory device 150 need not perform the program operation through the ISPP scheme to the memory cells having the threshold voltages of the target voltage level.

That is, as described above, according to the ISPP scheme, the program pulse PGM_PUL is unconditionally applied to a word line corresponding to a page, to which a program operation is performed, and then the verify pulse VR_PUL is applied to the word line. The ISPP scheme may be effective when no data is programmed into the word line, that is, when all of memory cells coupled to the word line have threshold voltages under the target voltage level.

However, in a situation where a reprogram operation is to be performed, that is, in a situation where the program pulse PGM_PUL is applied again to a word line coupled to a memory cell that is already programmed with a data for reliability and stability of the programmed data, there may be over-programming. That is, when a reprogram operation is to be performed, some memory cells of a target word line corresponding to a page, to which the reprogram operation is performed, may have threshold voltages under the target voltage level and other memory cells of the target word line may have threshold voltages of the target voltage level. In this situation, the memory cells having threshold voltages of the target voltage level may be over-programmed when the program pulse PGM_PUL is unconditionally applied to the target word line through the ISPP scheme.

In order to prevent the over-programming, the nonvolatile memory device 150 may first perform a verify operation and then may perform the well-known program operation according to the ISPP scheme under the control of the controller 130.

For example, referring to FIG. 7B, the nonvolatile memory device 150 may first perform a verify operation by using the verify pulse VR_PUL and then may perform the well-known program operation according to the ISPP scheme, according to the result of the verification operation during the second program operation 514 under the control of the controller 130.

The nonvolatile memory device 150 may further check whether a program operation to be performed to each of the plurality of pages P0 to P5 meets an operation condition for the reprogram. The nonvolatile memory device 150 may perform the second program operation 514 to the plurality of pages, each of which a program operation meets the operation condition for the reprogram. On the other hand, the nonvolatile memory device 150 may perform the first program operation 512 to the plurality of pages, each of which a program operation does not meet the operation condition for the reprogram.

The controller 130 may determine whether a program operation to be performed in the memory system 110 is a normal program operation or a reprogram operation, and may selectively perform one between the first and second program operation according to the result of the determining of whether a program operation to be performed in the memory system 110 is a normal program operation or a reprogram operation.

Therefore, the controller 130 in accordance with an embodiment of the present invention may check whether a program operation to be performed to each of the plurality of pages P0 to P5 included in the nonvolatile memory device 150 meets an operation condition for the reprogram operation.

Referring to FIGS. 5 and 6, the ECC unit 138 shown in FIG. 5 may correct failed bits of error-including read data R_DATA to recover the error-including read data R_DATA to become recovered data RC_R_DATA when the error-including read data R_DATA includes failed bits under a first threshold. Whether or not a number of error bits in the read data R_DATA is greater than the error bits threshold, which is described with reference to FIG. 1, may be determined through whether or not the error-including read data R_DATA includes failed bits over the first threshold, as described with reference to FIG. 5.

Referring to FIG. 5, the memory system 110 may be abruptly powered off due to a sudden power off (SPO) while the controller 130 is programming write data W_DATA, which is provided from the host 102, into a particular page among the plurality of pages P0 to P5. In this situation, the programming of the write data W_DATA into the plurality of pages P0 to P5 may interruptedly end. When the memory system 110 is powered back on after the SPO, the controller 130 may determine whether or not failed bits of read data R_DATA read from the particular page (hereinafter, referred to as ‘program-interrupted page’) are correctable by the ECC unit 138 (1301 of FIG. 5).

The program-interrupted page may be one among the plurality of pages P0 to P5 included in the nonvolatile memory device 150. The controller 130 may identify the program-interrupted page, into which the programming of the write data W_DATA has interruptedly ended due to the SPO, when the memory system 110 is powered back on. The operation of identifying the program-interrupted page, into which the programming of the write data W_DATA has interruptedly ended due to the SPO when the memory system 110 is powered back on is a well-known art and further description therefore will be omitted.

As a result of determining whether or not failed bits of read data R_DATA read from the program-interrupted page are correctable by the ECC unit 138 (1301 of FIG. 5) when the memory system 110 is powered back on after the SPO, the failed bits of read data R_DATA read from the program-interrupted page may be determined as correctable, that is, it may be possible to recover the error-including read data R_DATA read from the program-interrupted page, into which the programming of the write data W_DATA has interruptedly ended due to the SPO, to become recovered data RC_R_DATA by the ECC unit 138 when the error-including read data R_DATA includes failed bits under the first threshold. In this case, the controller 130 may program the recovered data RC_R_DATA into the program- interrupted page according to the second program operation 514 and then may provide the host 102 with an information (enabled WCOMPLETE) indicating that the program operation to the program-interrupted page has been completed (1302 of FIG. 5). At this time, the recovered data RC_R_DATA, which is recovered in the program-interrupted page by the ECC unit 138, may be the same as the write data W_DATA.

To summarize, the controller 130 may determine that it is possible to recover the program-interrupted page, into which the programming of write data W_DATA has interruptedly ended due to the sudden power off (SPO), through a reprogram operation when it is possible to recover error-including read data R_DATA read from the program-interrupted page to become recovered data RC_R_DATA by the ECC unit 138. In this case, the controller 130 may control the nonvolatile memory device 150 to perform a reprogram operation to the program-interrupted page with the recovered data RC_R_DATA, or, to program the recovered data RC_R_DATA into the program-interrupted page through the second program operation 514. At this time, the nonvolatile memory device 150 programs the recovered data RC_R_DATA through the second program operation 514 and thus memory cells already having the threshold voltage of the target voltage level may be prevented from the over-programming in the program-interrupted page.

On the other hand, as a result of determining whether or not failed bits of read data R_DATA read from the program-interrupted page are correctable by the ECC unit 138 (1301 of FIG. 5) when the memory system 110 is powered back on after the SPO, the failed bits of read data R_DATA read from the program-interrupted page may be determined as uncorrectable, that is, it may be impossible to recover the error-including read data R_DATA read, into which the programming of the write data W_DATA has interruptedly ended due to the SPO, to become recovered data RC_R_DATA by the ECC unit 138 when the error-including read data R_DATA includes failed bits over the first threshold. In this case, the controller 130 may change the program-interrupted page into an invalid state in order not to use the page, may provide the host 102 with an information (disabled WCOMPLETE) indicating that the program operation to the program-interrupted page has not been completed, may receive the write data W_DATA again from the host 102, and program the write data W_DATA into another one other than the program-interrupted page among the plurality of pages P0 to P5 according to the first program operation 512 (1303 of FIG. 5).

To summarize, the controller 130 may determine that it is impossible to recover the program-interrupted page, into which the programming of the write data W_DATA has interruptedly ended due to the SPO, through a reprogram operation when it is impossible to recover the error-including read data R_DATA read from the program-interrupted page to become recovered data RC_R_DATA by the ECC unit 138. In this case, the controller 130 may control the nonvolatile memory device 150 to perform the well-known program operation to another page other than the program-interrupted page among the plurality of pages P0 to P5 with the write data W_DATA, which is provided again from the host 102, or, to program the re-provided write data W_DATA into another page other than the program-interrupted page through the first program operation 512. Here, the another page other than the program-interrupted page may be an empty page not storing any data. Thus, the nonvolatile memory device 150 may perform the well-known program operation to the another page other than the program-interrupted page with the write data W_DATA according to the ISPP scheme without any problems.

Also, referring to FIG. 6, the controller 130 may perform a read operation to a program-interrupted page among the plurality of pages P0 to P5 in response to a request of the host 102, and may determine (1304 of FIG. 6) whether or not failed bits of read data R_DATA as a result of the read operation are between the first and second thresholds. When the failed bits of the read data R_DATA are between the first and second thresholds, the read data R_DATA may not be stably stored in the program-interrupted page even though it is possible to recover the error-including read data R_DATA to become recovered data RC_R_DATA by the ECC unit 138. The read data R_DATA may not be stably stored in the program-interrupted page when repetitive read operations are performed on the page or when a state of the page becomes bad after the read data R_DATA is programmed into the program-interrupted page.

Here, as an example, the second threshold may be 70% of the first threshold. Of course, it is obviously possible to set the second threshold to be greater or smaller than 70% of the first threshold according to various embodiments. Also, the program-interrupted page may be one among the plurality of pages P0 to P5 included in the nonvolatile memory device 150. The program-interrupted page may be the same as or different from the page described with reference to FIG. 5. The controller 130 may determine (1304 of FIG. 6) whether or not failed bits of read data R_DATA as a result of the read operation are between the first and second thresholds when the read data R_DATA read from the program-interrupted page includes the failed bits. On the other hand, the controller 130 may not have to determine (1304 of FIG. 6) whether or not failed bits of read data R_DATA as a result of the read operation are between the first and second thresholds when the read data R_DATA read from the program-interrupted page does not include any failed bits or includes a trivial number of failed bits so that the ECC unit 138 does not have to correct the trivial number of failed bits. The read data R_DATA read from the program-interrupted page may include the trivial number of failed bits, in which case the ECC unit 138 does not have to correct the trivial number of failed bits since the failed bits of the read data R_DATA may be recovered through a simple operation such as the parity check.

Therefore, when a number of failed bits of read data R_DATA read from the program-interrupted page is determined to be between first and second thresholds, the controller 130 may recover the error-including read data R_DATA to become recovered data RC_R_DATA by the ECC unit 138, and then may perform the second program operation 514 to the program-interrupted page with the recovered data RC_R_DATA (1305 of FIG. 6). Further, the second program process may be performed while the nonvolatile memory device 150 is in an idle state of the memory device 150 (1307 of FIG. 6). At this time, since the recovered data RC_R_DATA is reprogrammed into the program-interrupted page through the second program operation 514, memory cells already having the threshold voltage of the target voltage level may be prevented from the over-programming in the program-interrupted page.

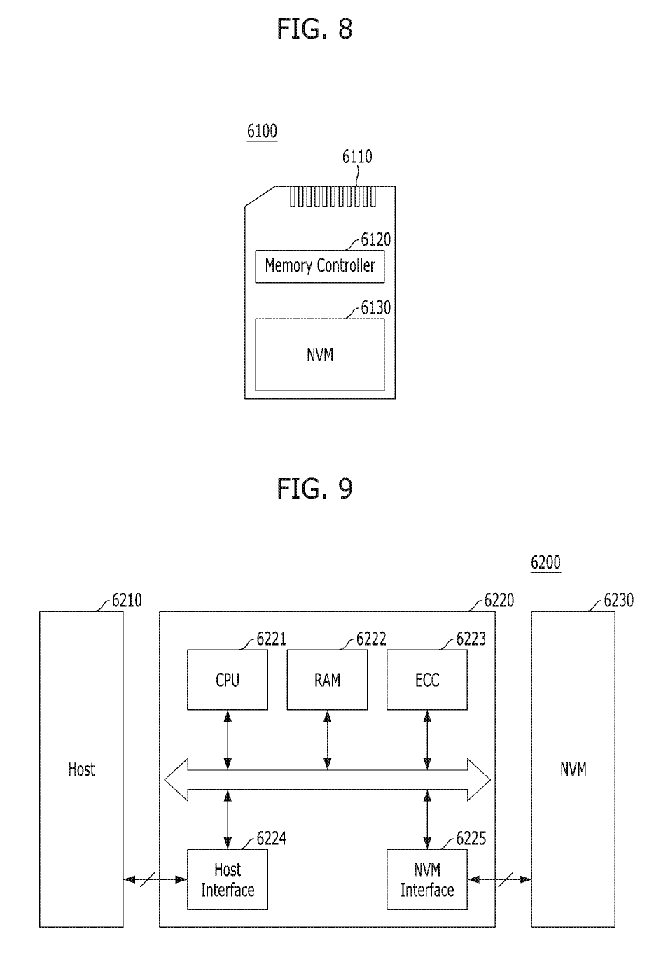

FIG. 8 is a diagram schematically illustrating an example of the data processing system including the memory system in accordance with an embodiment. FIG. 8 schematically illustrates a memory card system to which the memory system in accordance with an embodiment is applied.

Referring to FIG. 8, the memory card system 6100 may include a memory controller 6120, a memory device 6130 and a connector 6110.

More specifically, the memory controller 6120 may be connected to the memory device 6130 embodied by a nonvolatile memory, and configured to access the memory device 6130. For example, the memory controller 6120 may be configured to control read, write, erase and background operations of the memory device 6130. The memory controller 6120 may be configured to provide an interface between the memory device 6130 and a host, and drive firmware for controlling the memory device 6130. That is, the memory controller 6120 may correspond to the controller 130 of the memory system 110 described with reference to FIGS. 1 to 7B, and the memory device 6130 may correspond to the memory device 150 of the memory system 110 described with reference to FIGS. 1 to 7B.

Thus, the memory controller 6120 may include a RAM, a processing unit, a host interface, a memory interface and an error correction unit.

The memory controller 6120 may communicate with an external device, for example, the host 102 of FIG. 1 through the connector 6110. For example, as described with reference to FIGS. 1 to 7B, the memory controller 6120 may be configured to communicate with an external device through one or more of various communication protocols such as universal serial bus (USB), multimedia card (MMC), embedded MMC (eMMC), peripheral component interconnection (PCI), PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI, and Bluetooth. Thus, the memory system and the data processing system in accordance with an embodiment may be applied to wired/wireless electronic devices or particularly mobile electronic devices.

The memory device 6130 may be implemented by a nonvolatile memory. For example, the memory device 6130 may be implemented by various nonvolatile memory devices such as an erasable and programmable ROM (EPROM), an electrically erasable and programmable ROM (EEPROM), a NAND flash memory, a NOR flash memory, a phase-change RAM (PRAM), a resistive RAM (ReRAM), a ferroelectric RAM (FRAM), and a spin torque transfer magnetic RAM (STT-RAM).

The memory controller 6120 and the memory device 6130 may be integrated into a single semiconductor device. For example, the memory controller 6120 and the memory device 6130 may construct a solid-state driver (SSD) by being integrated into a single semiconductor device. Also, the memory controller 6120 and the memory device 6130 may construct a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC), and a universal flash storage (UFS).

FIG. 9 is a diagram schematically illustrating another example of the data processing system including the memory system in accordance with an embodiment.

Referring to FIG. 9, the data processing system 6200 may include a memory device 6230 having one or more nonvolatile memories and a memory controller 6220 for controlling the memory device 6230. The data processing system 6200 illustrated in FIG. 9 may serve as a storage medium such as a memory card (CF, SD, micro-SD or the like) or USB device, as described with reference to FIGS. 1 to 7B. The memory device 6230 may correspond to the memory device 150 in the memory system 110 illustrated in FIGS. 1 to 7B, and the memory controller 6220 may correspond to the controller 130 in the memory system 110 illustrated in FIGS. 1 to 7B.

The memory controller 6220 may control a read, write, or erase operation on the memory device 6230 in response to a request of the host 6210, and the memory controller 6220 may include one or more CPUs 6221, a buffer memory such as RAM 6222, an ECC circuit 6223, a host interface 6224 and a memory interface such as an NVM interface 6225.

The CPU 6221 may control overall operations on the memory device 6230, for example, read, write, file system management, and bad page management operations. The RAM 6222 may be operated according to control of the CPU 6221, and used as a work memory, buffer memory, or cache memory. When the RAM 6222 is used as a work memory, data processed by the CPU 6221 may be temporarily stored in the RAM 6222. When the RAM 6222 is used as a buffer memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC unit 138 illustrated in FIGS. 1 to 7B. As described with reference to FIGS. 1 to 7B, the ECC circuit 6223 may generate an error correction code (ECC) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. At this time, the ECC circuit 6223 may correct an error using the parity bit. For example, as described with reference to FIGS. 1 to 7B, the ECC circuit 6223 may correct an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe, or NAND interface. The memory controller 6220 may have a wireless communication function with a mobile communication protocol such as WiFi or Long Term Evolution (LTE). The memory controller 6220 may be connected to an external device, for example, the host 6210 or another external device, and then transmit/receive data to/from the external device. In particular, as the memory controller 6220 is configured to communicate with the external device through one or more of various communication protocols, the memory system and the data processing system in accordance with an embodiment may be applied to wired/wireless electronic devices or particularly a mobile electronic device.

FIG. 10 is a diagram schematically illustrating another example of the data processing system including the memory system in accordance with an embodiment. FIG. 10 schematically illustrates an SSD to which the memory system in accordance with an embodiment is applied.

Referring to FIG. 10, the SSD 6300 may include a controller 6320 and a memory device 6340 including a plurality of nonvolatile memories. The controller 6320 may correspond to the controller 130 in the memory system 110 of FIG. 1, and the memory device 6340 may correspond to the memory device 150 in the memory system of FIG. 1

More specifically, the controller 6320 may be connected to the memory device 6340 through a plurality of channels CH1 to CHi. The controller 6320 may include one or more processors 6321, a buffer memory 6325, an ECC circuit 6322, a host interface 6324 and a memory interface, for example, a nonvolatile memory interface 6326.

The buffer memory 6325 may temporarily store data provided from the host 6310 or data provided from a plurality of flash memories NVM included in the memory device 6340, or temporarily store meta data of the plurality of flash memories NVM, for example, map data including a mapping table. The buffer memory 6325 may be embodied by volatile memories such as DRAM, SDRAM, DDR SDRAM, LPDDR SDRAM, and GRAM, or nonvolatile memories such as FRAM, ReRAM, STT-MRAM, and PRAM. For convenience of description, FIG. 10 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 of FIG. 1 is applied may be provided to embody a data processing system, for example, RAID (Redundant Array of Independent Disks) system. At this time, the RAID system may include the plurality of SSDs 6300 and a RAID controller for controlling the plurality of SSDs 6300. When the RAID controller performs a program operation in response to a write command provided from the host 6310, the RAID controller may select one or more memory systems or SSDs 6300 according to a plurality of RAID levels, that is, RAID level information of the write command provided from the host 6310 in the SSDs 6300, and output data corresponding to the write command to the selected SSDs 6300. Furthermore, when the RAID controller performs a read command in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

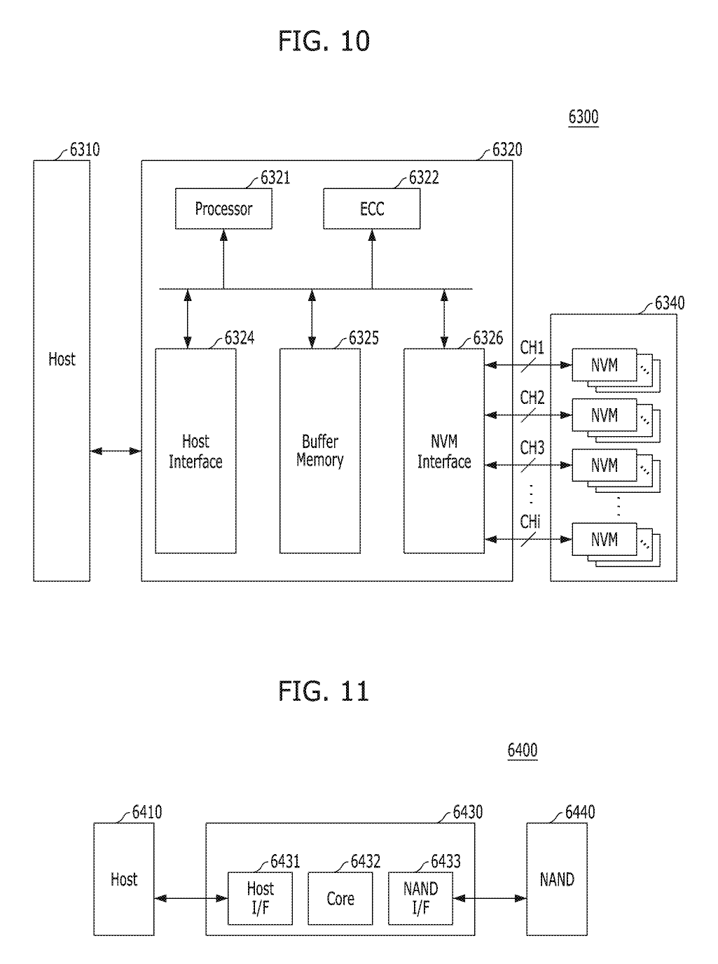

FIG. 11 is a diagram schematically illustrating another example of the data processing system including the memory system in accordance with an embodiment. FIG. 11 schematically illustrates an embedded Multi-Media Card (eMMC) to which the memory system in accordance with an embodiment is applied.

Referring to FIG. 11, the eMMC 6400 may include a controller 6430 and a memory device 6440 embodied by one or more NAND flash memories. The controller 6430 may correspond to the controller 130 in the memory system 110 of FIG. 1, and the memory device 6440 may correspond to the memory device 150 in the memory system 110 of FIG. 1.

More specifically, the controller 6430 may be connected to the memory device 6440 through a plurality of channels. The controller 6430 may include one or more cores 6432, a host interface 6431 and a memory interface, for example, a NAND interface 6433.

The core 6432 may control overall operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIGS. 1 to 7B. Furthermore, the host interface 6431 may serve as a serial interface, for example, UHS ((Ultra High Speed)-I/UHS-II) interface.

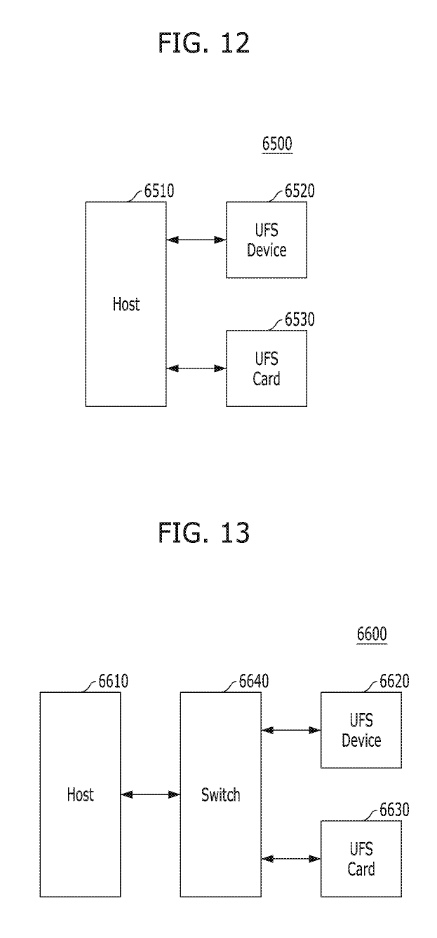

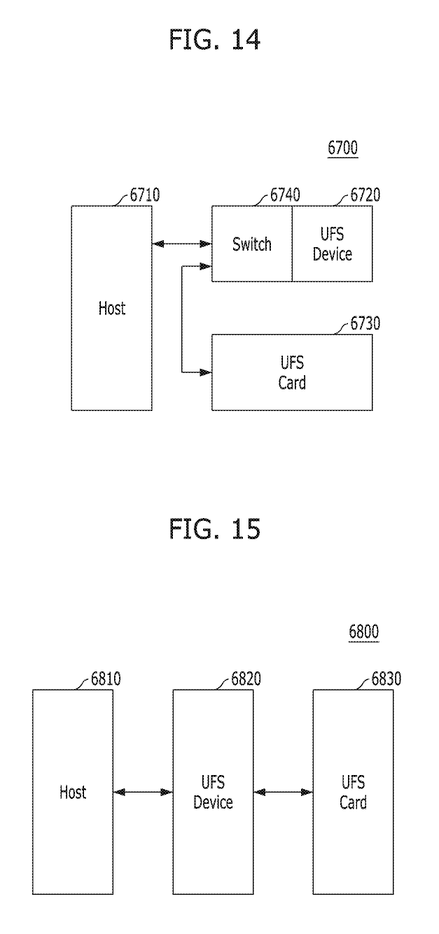

FIGS. 12 to 15 are diagrams schematically illustrating other examples of the data processing system including the memory system in accordance with an embodiment. FIGS. 12 to 15 schematically illustrate UFS (Universal Flash Storage) systems to which the memory system in accordance with an embodiment is applied.

Referring to FIGS. 12 to 15, the UFS systems 6500, 6600, 6700 and 6800 may include hosts 6510, 6610, 6710 and 6810, UFS devices 6520, 6620, 6720 and 6820 and UFS cards 6530, 6630, 6730 and 6830, respectively. The hosts 6510, 6610, 6710 and 6810 may serve as application processors of wired/wireless electronic devices or particularly mobile electronic devices, the UFS devices 6520, 6620, 6720 and 6820 may serve as embedded UFS devices, and the UFS cards 6530, 6630, 6730 and 6830 may serve as external embedded UFS devices or removable UFS cards.

The hosts 6510, 6610, 6710, and 6810, the UFS devices 6520, 6620, 6720, and 6820, and the UFS cards 6530, 6630, 6730, and 6830 in the respective UFS systems 6500, 6600, 6700, and 6800 may communicate with external devices, for example, wired/wireless electronic devices or particularly mobile electronic devices through UFS protocols, and the UFS devices 6520, 6620, 6720, and 6820 and the UFS cards 6530, 6630, 6730, and 6830 may be embodied by the memory system 110 illustrated in FIGS. 1 to 7B. For example, in the UFS systems 6500, 6600, 6700, and 6800, the UFS devices 6520, 6620, 6720, and 6820 may be embodied in the form of the data processing system 6200, the SSD 6300 or the eMMC 6400 described with reference to FIGS. 9 to 11, and the UFS cards 6530, 6630, 6730, and 6830 may be embodied in the form of the memory card system 6100 described with reference to FIG. 8.

Furthermore, in the UFS systems 6500, 6600, 6700, and 6800, the hosts 6510, 6610, 6710, and 6810, the UFS devices 6520, 6620, 6720, and 6820, and the UFS cards 6530, 6630, 6730, and 6830 may communicate with each other through an UFS interface, for example, MIPI M-PHY and MIPI UniPro (Unified Protocol) in MIPI (Mobile Industry Processor Interface). Furthermore, the UFS devices 6520, 6620, 6720 and 6820 and the UFS cards 6530, 6630, 6730 and 6830 may communicate with each other through various protocols other than the UFS protocol, for example, UFDs, MMC, SD, mini-SD, and micro-SD.

In the UFS system 6500 illustrated in FIGS. 1 to 7B, each of the host 6510, the UFS device 6520, and the UFS card 6530 may include UniPro. The host 6510 may perform a switching operation in order to communicate with the UFS device 6520 and the UFS card 6530. In particular, the host 6510 may communicate with the UFS device 6520 or the UFS card 6530 through link layer switching, for example, L3 switching at the UniPro. At this time, the UFS device 6520 and the UFS card 6530 may communicate with each other through link layer switching at the UniPro of the host 6510. In an embodiment, the configuration in which one UFS device 6520 and one UFS card 6530 are connected to the host 6510 has been exemplified for convenience of description. However, a plurality of UFS devices and UFS cards may be connected in parallel or in the form of a star to the host 6410, and a plurality of UFS cards may be connected in parallel or in the form of a star to the UFS device 6520 or connected in series or in the form of a chain to the UFS device 6520.

In the UFS system 6600 illustrated in FIGS. 1 to 7B, each of the host 6610, the UFS device 6620, and the UFS card 6630 may include UniPro, and the host 6610 may communicate with the UFS device 6620 or the UFS card 6630 through a switching module 6640 performing a switching operation, for example, through the switching module 6640 which performs link layer switching at the UniPro, for example, L3 switching. The UFS device 6620 and the UFS card 6630 may communicate with each other through link layer switching of the switching module 6640 at UniPro. In an embodiment, the configuration in which one UFS device 6620 and one UFS card 6630 are connected to the switching module 6640 has been exemplified for convenience of description. However, a plurality of UFS devices and UFS cards may be connected in parallel or in the form of a star to the switching module 6640, and a plurality of UFS cards may be connected in series or in the form of a chain to the UFS device 6620.

In the UFS system 6700 illustrated in FIGS. 1 to 7B, each of the host 6710, the UFS device 6720, and the UFS card 6730 may include UniPro, and the host 6710 may communicate with the UFS device 6720 or the UFS card 6730 through a switching module 6740 performing a switching operation, for example, through the switching module 6740 which performs link layer switching at the UniPro, for example, L3 switching. At this time, the UFS device 6720 and the UFS card 6730 may communicate with each other through link layer switching of the switching module 6740 at the UniPro, and the switching module 6740 may be integrated as one module with the UFS device 6720 inside or outside the UFS device 6720. In an embodiment, the configuration in which one UFS device 6720 and one UFS card 6730 are connected to the switching module 6740 has been exemplified for convenience of description. However, a plurality of modules each including the switching module 6740 and the UFS device 6720 may be connected in parallel or in the form of a star to the host 6710 or connected in series or in the form of a chain to each other. Furthermore, a plurality of UFS cards may be connected in parallel or in the form of a star to the UFS device 6720.

In the UFS system 6800 illustrated in FIGS. 1 to 7B, each of the host 6810, the UFS device 6820 and the UFS card 6830 may include M-PHY and UniPro. The UFS device 6820 may perform a switching operation in order to communicate with the host 6810 and the UFS card 6830. In particular, the UFS device 6820 may communicate with the host 6810 or the UFS card 6830 through a switching operation between the M-PHY and UniPro module for communication with the host 6810 and the M-PHY and UniPro module for communication with the UFS card 6830, for example, through a target identifier (ID) switching operation. At this time, the host 6810 and the UFS card 6830 may communicate with each other through target ID switching between the M-PHY and UniPro modules of the UFS device 6820. In an embodiment, the configuration in which one UFS device 6820 is connected to the host 6810 and one UFS card 6830 is connected to the UFS device 6820 has been exemplified for convenience of description. However, a plurality of UFS devices may be connected in parallel or in the form of a star to the host 6810, or connected in series or in the form of a chain to the host 6810, and a plurality of UFS cards may be connected in parallel or in the form of a star to the UFS device 6820, or connected in series or in the form of a chain to the UFS device 6820.

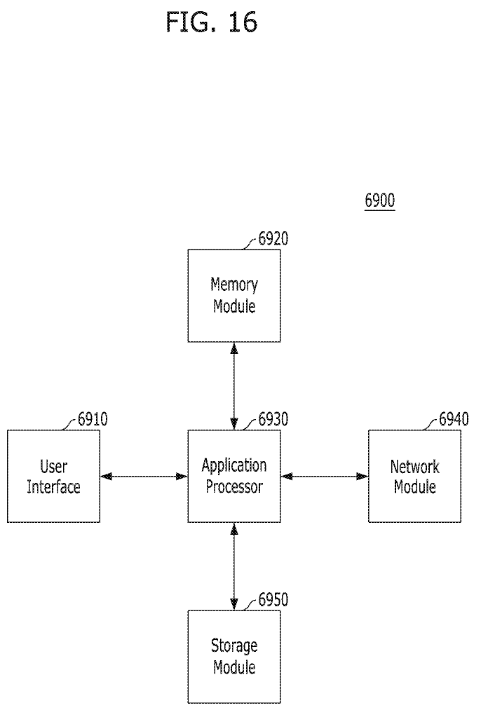

FIG. 16 is a diagram schematically illustrating another example of the data processing system including the memory system in accordance with an embodiment. FIG. 16 is a diagram schematically illustrating a user system to which the memory system in accordance with an embodiment is applied.

Referring to FIG. 16, the user system 6900 may include an application processor 6930, a memory module 6920, a network module 6940, a storage module 6950, and a user interface 6910.

More specifically, the application processor 6930 may drive components included in the user system 6900, for example, an OS, and include controllers, interfaces and a graphic engine which control the components included in the user system 6900. The application processor 6930 may be provided as a System-on-Chip (SoC).

The memory module 6920 may be used as a main memory, work memory, buffer memory, or cache memory of the user system 6900. The memory module 6920 may include a volatile RAM such as DRAM, SDRAM, DDR SDRAM, DDR2 SDRAM, DDR3 SDRAM, LPDDR SDARM, LPDDR3 SDRAM, or LPDDR3 SDRAM, or a nonvolatile RAM such as PRAM, ReRAM, MRAM, or FRAM. For example, the application processor 6930 and the memory module 6920 may be packaged and mounted, based on package on package (POP).

The network module 6940 may communicate with external devices. For example, the network module 6940 may not only support wired communication, but may also support various wireless communication protocols such as code division multiple access (CDMA), global system for mobile communication (GSM), wideband CDMA (WCDMA), CDMA-2000, time division multiple access (TDMA), long term evolution (LTE), worldwide interoperability for microwave access (Wimax), wireless local area network (WLAN), ultra-wideband (UWB), Bluetooth, wireless display (WI-DI), thereby communicating with wired/wireless electronic devices or particularly mobile electronic devices. Therefore, the memory system and the data processing system, can be applied to wired/wireless electronic devices. The network module 6940 may be included in the application processor 6930.

The storage module 6950 may store data, for example, data received from the application processor 6930, and then may transmit the stored data to the application processor 6930. The storage module 6950 may be embodied by a nonvolatile semiconductor memory device such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6900. The storage module 6950 may correspond to the memory system 110 described with reference to FIGS. 1 to 7B. Furthermore, the storage module 6950 may be embodied as an SSD, eMMC, and UFS as described above with reference to FIGS. 10 to 15.

The user interface 6910 may include interfaces for inputting data or commands to the application processor 6930 or outputting data to an external device. For example, the user interface 6910 may include user input interfaces such as a keyboard, a keypad, a button, a touch panel, a touch screen, a touch pad, a touch ball, a camera, a microphone, a gyroscope sensor, a vibration sensor, and a piezoelectric element, and user output interfaces such as a liquid crystal display (LCD), an organic light emitting diode (OLED) display device, an active matrix OLED (AMOLED) display device, an LED, a speaker, and a motor.

Furthermore, when the memory system 110 of FIG. 1 is applied to a mobile electronic device of the user system 6900, the application processor 6930 may control overall operations of the mobile electronic device, and the network module 6940 may serve as a communication module for controlling wired/wireless communication with an external device. The user interface 6910 may display data processed by the processor 6930 on a display/touch module of the mobile electronic device, or support a function of receiving data from the touch panel.

According to the exemplary embodiments of the present invention, the memory system and the method for operating the memory system may be able to minimize the complexity and performance deterioration of the memory system, maximize the usage efficiency of a memory device, and rapidly and stably process data into a memory device.

While the present invention has been described with respect to specific embodiments, it will be apparent to those skilled in the art that various changes and modifications may be made without departing from the spirit and scope of the invention as defined in the following claims.

What is claimed is:

1. A memory system comprising:
a nonvolatile memory device including a plurality of pages, and suitable for performing one among a first program operation of performing program and verify operations according to an incremental step pulse programming (ISPP) scheme and a second program operation of first performing a verify operation and then performing program and verify operations according to the ISPP scheme when the program operation is to be performed to each of the plurality of pages; and
a controller suitable for controlling the nonvolatile memory device to perform the second program operation when a target page meets an operation condition of a reprogram, and to perform the first program operation when the target page does not meet the operation condition of the reprogram.

2. The memory system of claim 1, wherein the controller includes an ECC unit suitable for recovering, when a read data read from each of the plurality of pages include failed bits under a first threshold, the read data by correcting the failed bits.

3. The memory system of claim 2,
wherein the controller determines, when a program operation is interrupted due to a sudden power off (SPO) while programming an input data into one among the plurality of pages and a power is back on again, whether or not failed bits of a read data read from the program-interrupted page are correctable through the ECC unit, and
wherein the controller programs, when the failed bits of the read data read from the program-interrupted page are determined to be correctable through the ECC unit, a recovered data into the program-interrupted page through the second program operation and provides the host with information indicating completion of the second program operation to the program-interrupted page.

4. The memory system of claim 3, wherein, when the failed bits of the read data read from the program-interrupted page are determined to be uncorrectable through the ECC unit, the controller invalidates the program-interrupted page, provides the host with information indicating program failure of the program-interrupted page, receives the input data again from the host, and programs the re-provided input data into another page other than the program-interrupted page through the first program operation.

5. The memory system of claim 2,
wherein the controller performs a read determination operation of determining whether or not failed bits of read data read from the program-interrupted page are over a predetermined second threshold smaller than the first threshold even when the failed bits of the read data are under the first threshold, and
wherein the controller performs, when failed bits of read data read from the program-interrupted page are determined to be over a second threshold even when the failed bits of the read data are under the first threshold as a result of the read determination operation, a make-up program operation of programming a recovered data, which is recovered by the ECC unit, into the program-interrupted page through the second program operation.

6. The memory system of claim 5,
wherein the controller simultaneously performs the read determination operation when a read data read from the program-interrupted page as a result of a read operation performed in response to a request from the host includes failed bits, and
wherein the controller performs, after the read determination operation, the make-up program operation when the nonvolatile memory device is in an idle state.

7. The memory system of claim 5, wherein the second threshold is 70% of the first threshold.

8. An operating method of a memory system including a nonvolatile memory device including a plurality of pages, and suitable for performing one among a first program operation of performing program and verify operations according to an incremental step pulse programming (ISPP) scheme and a second program operation of first performing a verify operation and then performing program and verify operations according to the ISPP scheme when the program operation is to be performed to each of the plurality of pages, the operating method comprising:
a determining step of determining whether or not each of the plurality of pages meets an operation condition of a reprogram; and
a program controlling step of controlling the nonvolatile memory device to perform the second program operation when a target page meets an operation condition of a reprogram, and to perform the first program operation when the target page does not meet the operation condition of the reprogram.

9. The operating method of claim 8, further comprising a recovering step of recovering, when a read data read from each of the plurality of pages includes failed bits under a first threshold, the read data by correcting the failed bits.

10. The operating method of claim 9, wherein the determining step includes a recovery determining step of determining, when a program operation is interrupted due to a sudden power off (SPO) while programming an input data provided from a host into a program-interrupted page and a power is back on again, whether or not failed bits of a read data read from the program-interrupted page are correctable through the recovering step.

11. The operating method of claim 10, wherein when the failed bits of the read data read from the program-interrupted page are determined to be correctable through the ECC unit by the recovery determining step, the program controlling step includes:
programing a recovered data, which is recovered through the recovering step, into the program-interrupted page through the second program operation; and
providing the host with information indicating completion of the second program operation to the program-interrupted page.

12. The operating method of claim 11, wherein when the failed bits of the read data read from the program-interrupted page are determined to be uncorrectable through the ECC unit by the recovery determining step, the program controlling step includes:
invalidating the program-interrupted page;
providing the host with information indicating program failure of the program-interrupted page; and
receiving, after the second provision step, the input data again from the host, and programming the re-provided input data into another page other than the program-interrupted page through the first program operation.

13. The operating method of claim 9, wherein the determining step includes a read determination step of determining whether or not failed bits of read data read from the program-interrupted page are over a predetermined second threshold smaller than the first threshold even when the failed bits of the read data are under the first threshold.

14. The operating method of claim 13, wherein when failed bits of read data read from the program-interrupted page are determined to be over a second threshold even when the failed bits of the read data are under the first threshold as a result of the read determination step, the program controlling step includes a make-up program step of programming a recovered data, which is recovered by the recovering step, into the program-interrupted page through the second program operation.

15. The operating method of claim 14, further comprising:
simultaneously performing the read determination step when a read data read from the program-interrupted page as a result of a read operation performed in response to a request from the host includes failed bits; and
performing, after the read determination step, the make-up program step when the nonvolatile memory device is in an idle state.

16. The operating method of claim 13, wherein the second threshold is 70% of the first threshold.

17. A memory system comprising:
a memory device including a plurality of pages; and
a controller suitable for controlling the memory device to perform a verification operation and then a program operation to a program-interrupted one among the plurality of pages,
wherein the controller detects one or more under a target voltage level among memory cells included in the program-interrupted page through the verification operation, and
wherein the program operation may include one or more cycles of program and verification to the memory cells under the target voltage level.
